(19) United States
(12) Patent Application Publication
(10) Pub. No.: US 2004/0240307 A1
(43) Pub. Date: Dec. 2, 2004

(54) Semiconductor device, semiconductor circuit, electronic equipment, and method of controlling clock-supply

(75) Inventor: Makoto Kudo, Fujimi-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/803,948

(22) Filed: Mar. 19, 2004

(30) Foreign Application Priority Data
Mar. 20, 2003 (JP) 2003-078088

(51) Int. Cl. G11C 5/00

(52) U.S. Cl. 365/232

(57) ABSTRACT

The invention can provide a device, such as a semiconductor device, that accesses at least one semiconductor storage medium. The semiconductor device can include a given bus master that functions as a bus master, a bus interface that controls access to semiconductor storage media based on access request from the bus master, and a clock-supply-control circuit that controls the presence of the supply of a clock to the bus master based on access state information that indicates a state of access to the semiconductor storage media. The clock-supply-control circuit can stop the supply of the clock to the bus master if the bus interface is at a BUSY state, and supply the clock to the bus master if the bus interface is not at a BUSY state. Accordingly, a power consumption of a semiconductor device that accesses at least one semiconductor storage medium can be reduced.

### CROSS-REFERENCE TO RELATED APPLICATION

The disclosure of Japanese Application No. 2003-078088 filed on Mar. 20, 2003, including the specification, drawings and claims is incorporated herein by reference in its entirety.

### BACKGROUND OF THE INVENTION

1. Field of Invention

The present invention relates to a semiconductor device, a semiconductor circuit, electronic equipment, and a method of controlling clock-supply.

2. Description of Related Art

In a semiconductor device that accesses semiconductor storage media, such as an SRAM and an SDRAM, a clock is constantly supplied to a bus master, such as a CPU at a power-on state. See, for example, Japanese Unexamined Patent Application Publication No. 9-83247. A clock therefore can be supplied to a CPU even when the CPU is at a state of waiting access to a semiconductor storage medium, and thus is at a low speed for example, causing unnecessary power consumption.

### SUMMARY OF THE INVENTION

In view of the above problem, the present invention is intended to reduce the power consumption of a semiconductor device that accesses a semiconductor storage medium. A semiconductor device of the present invention that accesses at least one semiconductor storage medium can include a given bus master block that functions as a bus master, and a bus interface block that controls access to the at least one semiconductor storage medium based on request for access to the at least one semiconductor storage medium from the given bus master block. The semiconductor device can also include a clock-supply-control circuit that controls the presence of the supply of a clock to the bus master block based on access state information that indicates a state of access to the at least one semiconductor storage medium. The clock-supply-control circuit includes a circuit. The circuit implements at least one of control for stopping the supply of the clock to the bus master block if the circuit determines that the bus interface is at a BUSY state, and control for supplying the clock to the bus master block if the circuit determines that the bus interface is at a non-BUSY state, based on the access state information.

A semiconductor circuit of the present invention that controls the presence of the supply of a clock to a given bus master block functioning as a bus master can include a control-signal generator that generates a clock-supply-control signal for bus master for instructing the presence of the supply of the clock to the given bus master block, based on access state information that indicates a state of access to at least one semiconductor storage medium. The semiconductor circuit also can include a control circuit that controls the presence of the supply of the clock generated from a clock generator to the given bus master block, based on the clock-supply-control signal for bus master. The control-signal generator disables the clock-supply-control signal for bus master if the access state information indicates that access is in execution. The control circuit includes a circuit that controls so as to stop the supply of the clock generated from the clock generator to the given bus master block if the clock-supply-control signal for bus master is disabled.

Electronic equipment of the present invention can include a semiconductor device that includes any of the above-described semiconductor devices, or any of the above-described semiconductor circuits, means that receives input information, and means that outputs a result processed by an information-processing device based on the input information.

A method of controlling clock-supply of the present invention that controls the presence of the supply of a clock to a bus master block of a semiconductor device can include a step of generating a clock-supply-control signal for bus master for instructing the presence of the supply of the clock to the given bus master block, based on access state information that indicates a state of access to at least one semiconductor storage medium. The method also can include a step of controlling the presence of the supply of the clock generated from a clock generator to the given bus master block, based on the clock-supply-control signal for bus master. The clock-supply-control signal for bus master is disabled if the access state information indicates that access is in execution. Control to stop the supply of the clock generated from the clock generator to the given bus master block is implemented if the clock-supply-control signal for bus master is disabled.

A semiconductor device of the present embodiment that accesses at least one semiconductor storage medium can include a given bus master block that functions as a bus master, a bus interface block that controls access to the at least one semiconductor storage medium based on request for access to the at least one semiconductor storage medium from the given bus master block. The semiconductor device can also include a clock-supply-control circuit that controls the presence of the supply of a clock to the bus master block based on access state information that indicates a state of access to the at least one semiconductor storage medium. The clock-supply-control circuit includes a circuit. The circuit implements at least one of control for stopping the supply of the clock to the bus master block if the circuit determines that the bus interface is at a BUSY state, and control for supplying the clock to the bus master block if the circuit determines that the bus interface is at a non-BUSY state, based on the access state information. As the given bus master block that functions as a bus master, there are, for example, a CPU, a high-speed SRAM, an MMU, a cache, and a DMA.

The clock-supply-control signal for bus master for controlling the presence of the supply of a clock to the bus master block may be disabled if the bus interface is regarded as being at a BUSY state based on the access state information. The supply of a clock may be stopped if the clock-supply-control signal for bus master is disabled. As the access state information, a request signal output from the bus master, a BUSY signal output from the bus interface, a valid signal output from the bus interface (the valid signal is enabled during the period of sending accessed data), etc. may be used. For example, the determination whether the bus interface is at a BUSY state or not may be implemented by using the BUSY signal.

According to the present embodiment, the supply of a clock to the bus master such as a CPU, a high-speed SRAM, an MMU, a cache, a DMAC can be stopped if the bus interface is at a BUSY state. The power of the device therefore can be lowered by stopping the supply of a clock to the bus master that is at a state of waiting access to a semiconductor storage medium, enabling the unnecessary power consumption to be prevented.

In the semiconductor device of the present embodiment, the clock-supply-control circuit implements a processing to stop the supply of the clock to the given bus master block after the completion of request output from the given bus master block. Here, after the completion of request from the bus master block means the time when the request signal output from the bus master block turns down the request (for example, the time when the request signal changes from H level to L level), and the like.

The case where the supply of a clock to the bus master block is stopped after the completion of request from the bus master block may be the case where, for example, the supply of a clock to the bus master block is stopped after the completion of the request from the bus master block is detected (for example, after the change of the request signal from H level to L level is detected). Otherwise, that may be the case where the supply of a clock to the bus master block is stopped after the bus interface block changes from a non-BUSY state (idle state) to a BUSY state, or after at least the time of one clock passes after the change (during the period, the request from the bus master block is completed).

According to the present embodiment, the supply of a clock to the given bus master block can be stopped after the completion of the request output from the given bus master block, so that the situation where a clock to the bus master is stopped before the bus master turns down the request can be avoided.

A semiconductor circuit of the present embodiment that controls the presence of the supply of a clock to a given bus master block functioning as a bus master can include a control-signal generator that generates a clock-supply-control signal for bus master for instructing the presence of the supply of the clock to the given bus master block, based on access state information that indicates a state of access to at least one semiconductor storage medium. The semiconductor circuit can also include a control circuit that controls the presence of the supply of the clock generated from a clock generator to the given bus master block, based on the clock-supply-control signal for bus master. The control-signal generator disables the clock-supply-control signal for bus master if the access state information indicates that access is in execution. The control circuit includes a circuit that controls so as to stop the supply of the clock generated from the clock generator to the given bus master block if the clock-supply-control signal for bus master is disabled.

The period when access is in execution includes the period when at least the bus interface accesses a semiconductor storage medium (for example, the period when the bus interface is at a BUSY state). As the access state information, the request signal output from the bus master, the BUSY signal output from the bus interface, the valid signal output from the bus interface (the valid signal is enabled during the period of sending accessed data), etc. may be used. For example, the determination whether the bus interface is at a BUSY state or not may be implemented by using the BUSY signal.

According to the present embodiment, the supply of a clock to the bus master, such as a CPU, a high-speed SRAM, an MMU, a cache, a DMAC can be stopped if access to a semiconductor storage medium is in execution. The power of the device can therefore be lowered by stopping the supply of a clock to the bus master that is at a state of waiting access to a semiconductor storage medium, enabling the unnecessary power consumption to be prevented.

In the semiconductor device of the present embodiment, the control-signal generator disables the clock-supply-control signal for bus master after the completion of request output from the given bus master block.

After the completion of request from the bus master block can mean the time when the request signal output from the bus master block turns down the request (for example, the time when the request signal changes from H level to L level), and the like. The case where the supply of a clock to the bus master block is stopped after the completion of the request from the bus master block may be the case where, for example, the supply of a clock to the bus master block is stopped after the completion of the request from the bus master block is detected (for example, after the change of the request signal from H level to L level is detected). Otherwise, that may be the case where the supply of a clock to the bus master block is stopped after the bus interface block changes from a non-BUSY state (idle state) to a BUSY state, or after at least the time of one clock passes after the change (during the period, the request from the bus master block is completed).

According to the present embodiment, the supply of a clock to the given bus master block can be stopped after the completion of the request output from the given bus master block, so that the situation where a clock to the bus master is stopped before the bus master turns down the request can be avoided.

Electronic equipment of the present embodiment can include a semiconductor device that includes any of the above-described semiconductor devices, or any of the above-described semiconductor circuits, means that receives input information, and means that outputs a result processed by an information-processing device based on the input information.

A method of controlling clock-supply of the present embodiment that controls the presence of the supply of a clock to a bus master block of a semiconductor device can include a step of generating a clock-supply-control signal for bus master for instructing the presence of the supply of the clock to the given bus master block, based on access state information that indicates a state of access to at least one semiconductor storage medium. The method also includes a step of controlling the presence of the supply of the clock generated from a clock generator to the given bus master block, based on the clock-supply-control signal for bus master. The clock-supply-control signal for bus master is disabled if the access state information indicates that access is in execution. Control to stop the supply of the clock generated from the clock generator to the given bus master block is implemented if the clock-supply-control signal for bus master is disabled.

In the method of controlling clock-supply of the present embodiment, the clock-supply-control signal for bus master is disabled after the completion of request output from the given bus master block.

A semiconductor device of the present embodiment that accesses at least one semiconductor storage medium can include a given bus master block that functions as a bus master, and a bus interface block that controls access to the at least one semiconductor storage medium based on request for access to the at least one semiconductor storage medium from the given bus master block. The semiconductor device also can include a clock-supply-control circuit that controls the presence of the supply of a clock to the bus interface block based on access state information that indicates a state of access to the at least one semiconductor storage medium. The clock-supply-control circuit includes a circuit. The circuit implements at least one of control for stopping the supply of the clock to the bus interface block if the circuit determines that access is not in execution, and control for supplying the clock to the bus interface block if the circuit determines that access is in execution, based on the access state information.

As the given bus master block that functions as a bus master, there are, for example, a CPU, a high-speed SRAM, an MMU, a cache, and a DMA.

The clock-supply-control signal for bus interface for controlling the presence of the supply of a clock to the bus interface block may be disabled if access is regarded as not being in execution based on the access state information. The supply of a clock to the bus interface may be stopped if the clock-supply-control signal for bus interface is disabled.

As the access state information, the request signal output from the bus master, the BUSY signal output from the bus interface, the valid signal output from the bus interface (the valid signal is enabled during the period of sending accessed data), and the like, may be used. For example, the period of the request being on or a state being a BUSY state may be regarded as the period when access is in execution by using the BUSY signal and the request signal. Otherwise, the period of the request being on, a state being a BUSY state, or being valid may be regarded as the period when access is in execution by using the BUSY signal, the request signal, and the valid signal.

According to the present embodiment, the supply of a clock to the bus interface can be stopped if access is in execution. The power of the device therefore can be lowered by stopping the supply of a clock to the bus interface that is at an idle state, enabling the unnecessary power consumption to be prevented.

In the semiconductor device of the present embodiment, the at least one semiconductor storage medium can include at least a plurality of semiconductor storage media. The bus interface block can include a common bus interface block that in common implements operation required for access control when access to any of the semiconductor storage media is in execution, and dedicated bus interface blocks that each correspond to a certain one of the semiconductor storage media and that each implement operation required for access control only when access to the certain one of the semiconductor storage media is in execution. The clock-supply-control circuit detects any of the semiconductor storage media that is other than any of the semiconductor storage media that is to be accessed based on accessed-medium information indicating which semiconductor storage medium is to be accessed, and controls so as to stop the supply of the clock to any of the dedicated bus interface blocks for the any of the semiconductor storage media that is other than the any of the semiconductor storage media that is to be accessed and supply the clock to any of the dedicated bus interface blocks for the any of the semiconductor storage media that is to be accessed.

According to the present embodiment, the supply of a clock to the dedicated bus interface block for the semiconductor storage medium not to be accessed can be stopped even when the bus interface is accessing, so that the reduction of the power consumption can be more minutely implemented.

In the semiconductor device of the present embodiment, the clock-supply-control circuit implements a processing to stop the supply of the clock to the bus interface block after the completion of a valid signal output from the bus interface block.

After the completion of a valid signal output from the bus interface block means the time when, for example, the valid signal output from the bus interface block changes from H level to L level.

The case where the supply of a clock to the bus interface block is stopped after the completion of the valid signal output from the bus interface block may be the case where, for example, the supply of a clock to the bus interface block is stopped after the output of the valid signal from the bus interface block is detected. Otherwise, that may be the case where the supply of a clock to the bus interface block is stopped after the bus interface block changes from a BUSY state to a non-BUSY state (after the BUSY signal changes from H level to L level), or after at least the time of one clock passes after the change (during the period, the bus interface block outputs the valid signal).

This enables a clock to be supplied to the bus interface block until the bus interface disables the valid signal.

A semiconductor circuit of the present embodiment that controls the presence of the supply of a clock to a bus interface block controlling access to at least one semiconductor storage medium based on request for access to the at least one semiconductor storage medium from a bus master block includes a control-signal generator that generates a clock-supply-control signal for bus interface for instructing the presence of the supply of the clock to the given bus interface block, based on access state information that indicates a state of access to the at least one semiconductor storage medium. The semiconductor circuit can also include a control circuit that controls the presence of the supply of the clock generated from a clock generator to the given bus interface block, based on the clock-supply-control signal for bus interface. The control-signal generator disables the clock-supply-control signal for bus interface if the access state information indicates that access is not in execution. The control circuit includes a circuit that controls so as to stop the supply of the clock generated from the clock generator to the bus interface block if the clock-supply-control signal for bus interface is disabled.

The period when access is in execution includes the period when at least the bus interface accesses a semiconductor storage medium (for example, the period when the bus interface is at a BUSY state). As the access state information, the request signal output from the bus master, the BUSY signal output from the bus interface, the valid signal output from the bus interface (the valid signal is enabled during the period of sending accessed data), etc. may be used. For example, the period of the request being on or a state being a BUSY state may be regarded as the period when access is in execution by using the BUSY signal or the request signal. Otherwise, the period of the request being on, a state being a BUSY state, or being valid may be regarded as the period when access is in execution by using the BUSY signal, the request signal, and the valid signal.

According to the present embodiment, the supply of a clock to the bus interface can be stopped if access is in execution. The power of the device therefore can be lowered by stopping the supply of a clock to the bus interface that is at an idle state, enabling the unnecessary power consumption to be prevented.

In the semiconductor circuit of the present embodiment, the at least one semiconductor storage medium can include at least a plurality of semiconductor storage media. The bus interface block can include a common bus interface block that in common implements operation required for access control when access to any of the semiconductor storage media is in execution, and dedicated bus interface blocks that each correspond to a certain one of the semiconductor storage media and that each implement operation required for access control only when access to the certain one of the semiconductor storage media is in execution. The control-signal generator detects any of the semiconductor storage media that is other than any of the semiconductor storage media that is to be accessed based on accessed-medium information shown by the bus interface block and indicating which semiconductor storage medium is to be accessed, so as to disable a clock-supply-control signal for dedicated bus interface to any of the dedicated bus interface blocks for the any of the semiconductor storage media that is other than the any of the semiconductor storage media that is to be accessed. The control circuit includes a circuit that controls so as to stop the supply of the clock generated from the clock generator to the any of the dedicated bus interface blocks for the any of the semiconductor storage media that is other than the any of the semiconductor storage media that is to be accessed if the clock-supply-control signal for dedicated bus interface is disabled.

According to the present embodiment, the supply of a clock to the dedicated bus interface block for the semiconductor storage medium not to be accessed can be stopped even when the bus interface is accessing, so that the reduction of the power consumption can be more minutely implemented.

In the semiconductor circuit of the present embodiment, the control-signal generator disables the clock-supply-control signal for dedicated bus interface after the completion of a valid signal from the bus interface block.

After the completion of a valid signal output from the bus interface block means the time when, for example, the valid signal output from the bus interface block changes from H level to L level. The case where the supply of a clock to the bus interface block is stopped after the completion of a valid signal output from the bus interface block may be the case where, for example, the supply of a clock to the bus interface block is stopped after the output of the valid signal from the bus interface block is detected. Otherwise, that may be the case where the supply of a clock to the bus interface block is stopped after the bus interface block changes from a BUSY state to a non-BUSY state (after the BUSY signal changes from H level to L level), or after at least the time of one clock passes after the change (during the period, the bus interface block outputs the valid signal). This enables a clock to be supplied to the bus interface block until the bus interface turns down the valid signal.

The present embodiment includes a semiconductor device that includes any of the above-described semiconductor devices, or any of the above-described semiconductor circuits, means that receives input information, and means that outputs a result processed by an information-processing device based on the input information.

A method of controlling clock-supply of the present embodiment that controls the presence of the supply of a clock to a bus interface block of a semiconductor device includes a step of generating a clock-supply-control signal for bus interface for instructing the presence of the supply of the clock to the given bus interface block, based on access state information that indicates a state of access to at least one semiconductor storage medium. The method can also include a step of controlling the presence of the supply of the clock generated from a clock generator to the given bus interface block, based on the clock-supply-control signal for bus interface. The clock-supply-control signal for bus interface is disabled if the access state information indicates that access is not in execution. Control to stop the supply of the clock generated from the clock generator to the bus interface block is implemented if the clock-supply-control signal for bus interface is disabled.

In the method of controlling clock-supply of the present embodiment, the at least one semiconductor storage medium includes at least a plurality of semiconductor storage media. The bus interface block includes a common bus interface block that in common implements operation required for access control when access to any of the semiconductor storage media is in execution, and dedicated bus interface blocks that each correspond to a certain one of the semiconductor storage media and that each implement operation required for access control only when access to the certain one of the semiconductor storage media is in execution. Any of the semiconductor storage media that is other than any of the semiconductor storage media that is to be accessed is detected based on accessed-medium information shown by the bus interface block and indicating which semiconductor storage medium is to be accessed, and a clock-supply-control signal for dedicated bus interface to any of the dedicated bus interface blocks for the any of the semiconductor storage media that is other than the any of the semiconductor storage media that is to be accessed is disabled. Control is implemented so that the supply of the clock generated from the clock generator to the any of the dedicated bus interface blocks for the any of the semiconductor storage media that is other than the any of the semiconductor storage media that is to be accessed is stopped if the clock-supply-control signal for dedicated bus interface is disabled.

In the method of controlling clock-supply of the present embodiment, the clock-supply-control signal for dedicated bus interface can be disabled after the completion of a valid signal from the bus interface block.

### BRIEF DESCRIPTION OF THE DRAWINGS

The invention will be described with reference to the accompanying drawings, wherein like numerals reference like elements, and wherein:

FIG. 1 is a diagram for explaining an example of a semiconductor device and a semiconductor circuit of the present embodiment;

FIG. 2 is a diagram for explaining an example of the structure of a control-signal generator of the present embodiment;

FIG. 3 is a timing chart diagram of each signal of FIG. 2;

FIG. 4 is a diagram for explaining an example of the structure of a control circuit of the present embodiment;

FIG. 5 is a timing chart diagram of each signal of FIG. 4;

FIG. 6 is a diagram for explaining about the periods when a clock is supplied to the given bus master block and when a clock is supplied to the bus interface block;

FIG. 7 is an example of a hardware block diagram of a microcomputer including the semiconductor device or the semiconductor circuit of the present embodiment;

FIG. 8 is an example of a block diagram of electronic equipment including the microcomputer; and

FIGS. 9(A) through (C) show examples of an external view of a variety of electronic equipment.

### DETAILED DESCRIPTION OF PREFERRED EMBODIMENTS

Preferred embodiments of the present invention will be described in detail below with reference to accompanying drawings.

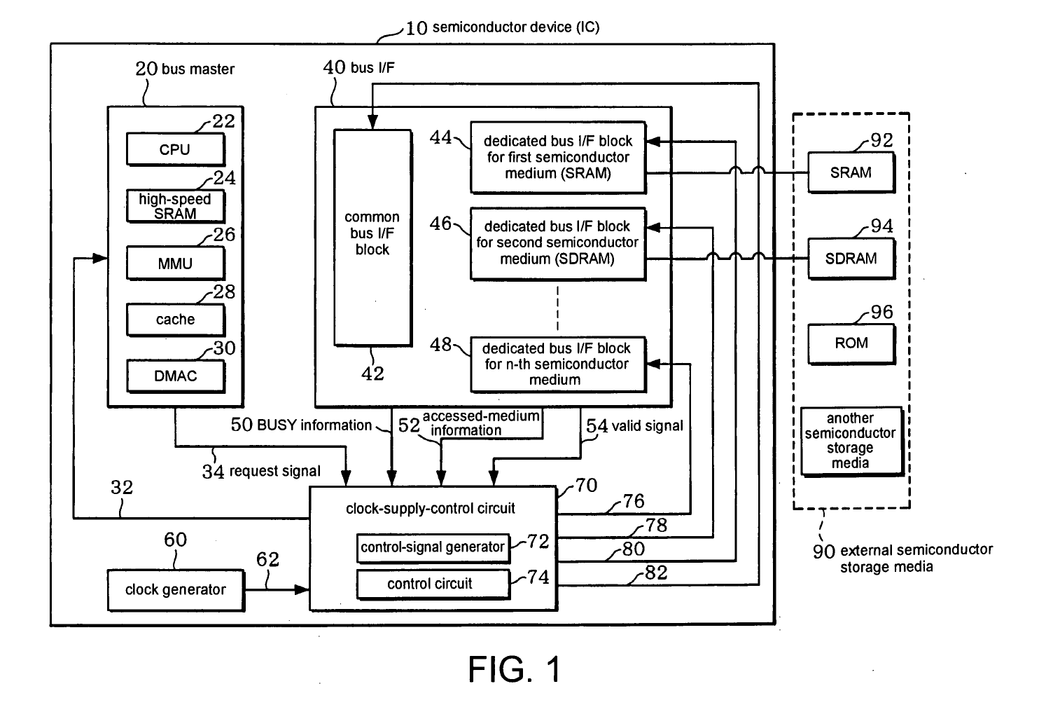

FIG. 1 is a diagram for explaining an example of a semiconductor device and a semiconductor circuit of the present embodiment. A semiconductor device 10 of the present embodiment is a semiconductor device that accesses semiconductor storage media 90 of the outside or inside (for example, an SRAM (Static Random Access Memory) 92, an SDRAM (Static Random Access Memory) 94, a ROM (Read only Memory) 96, and the like). The semiconductor device 10 of the present embodiment can include a given bus master block 20 functioning as a bus master 20 (for example, at least one of a CPU (a processor, in the broad sense) 22, a high-speed SRAM 24, an MMU (Memory Management Unit) 26, a cache 28, a DMAC (Direct Memory Access Controller) 30).

The semiconductor device 10 of the present embodiment can also include a bus interface 40 that controls access to a semiconductor storage medium based on request for access to the semiconductor storage medium from the given bus master block 20.

The semiconductor device 10 of the present embodiment can also include a clock-supply-control circuit 70. The clock-supply-control circuit 70 may implement a processing to stop the supply of a clock 32 to the bus master block 20, if access state information (for example, at least one of BUSY information 50, a request signal 34, and a valid signal 54) showing a state of access to the semiconductor storage media 90 indicates that access is in execution. In addition, the clock-supply-control circuit 70 may implement a processing to stop the supply of clocks 76, 78, 80, and 82 to the bus interface block 40, if the access state information (for example, at least one of the BUSY information 50, the request signal 34, and the valid signal 54) indicates that access is not in execution.

The clock-supply-control circuit 70 functions as the semiconductor circuit of the present embodiment that controls the supply and stop of a clock to the given bus master block 20 functioning as a bus master (for example, at least one of the CPU 22, the high-speed SRAM 24, the MMU 26, the cache 28, and the DMA 30).

The semiconductor circuit 70 of the present embodiment can include a control-signal generator 72. The control-signal generator 72 generates a clock-supply-control signal for instructing the supply or stop of a clock to the given bus master block, based on the access state information indicating a state of access to the semiconductor storage media 90 (for example, the SRAM 92, the SDRAM 94, the ROM 96, and the like). The semiconductor circuit 70 of the present embodiment also can include a control circuit 74. The control circuit 74 controls the supply or stop of a clock generated from a clock generator 60 to the given bus master block 20, based on the clock-supply-control signal.

The control-signal generator 72 may disable a clock-supply-control signal for bus master when the access state information indicates that access is in execution. The control circuit 74 may include a circuit that controls so that a clock generated from the clock generator is not supplied to the given bus master block when the clock-supply-control signal for bus master is disabled. Meanwhile, the control-signal generator 72 may enable the clock-supply-control signal for bus master when the access state information indicates that access is not in execution. The control circuit 74 may include a circuit that controls so that a clock generated from the clock generator is supplied to the given bus master block when the clock-supply-control signal for bus master is enabled.

The bus interface 40 may include a common bus interface block 42 that in common implements operation required for access control when access to any of the semiconductor storage media is in execution. The bus interface 40 may also include dedicated bus interface blocks 44, 46, and so on that each implement operation required for access control only when access to the certain semiconductor storage medium is in execution.

In this case, the clock-supply-control circuit 70 may control so that a semiconductor storage medium not to be accessed is detected based on accessed-medium information 52 shown by the bus interface block and indicating which semiconductor storage medium is to be accessed, and then the supply of a clock to the dedicated bus interface block for the semiconductor storage medium not to be accessed is stopped, while a clock is supplied to the common bus interface block 42 and the dedicated bus interface block for the semiconductor storage medium to be accessed. For example, the control-signal generator 72 may detect a semiconductor storage medium not to be accessed based on the accessed-medium information 52 shown by the bus interface block and indicating which semiconductor storage medium is to be accessed, and may disable a clock-supply-control signal for dedicated bus interface for the semiconductor storage medium not to be accessed. The control circuit 74 may control so that a clock generated from the clock generator is not supplied to the dedicated bus interface block for the semiconductor storage medium that is not accessed when the clock-supply-control signal for dedicated bus interface is disabled.

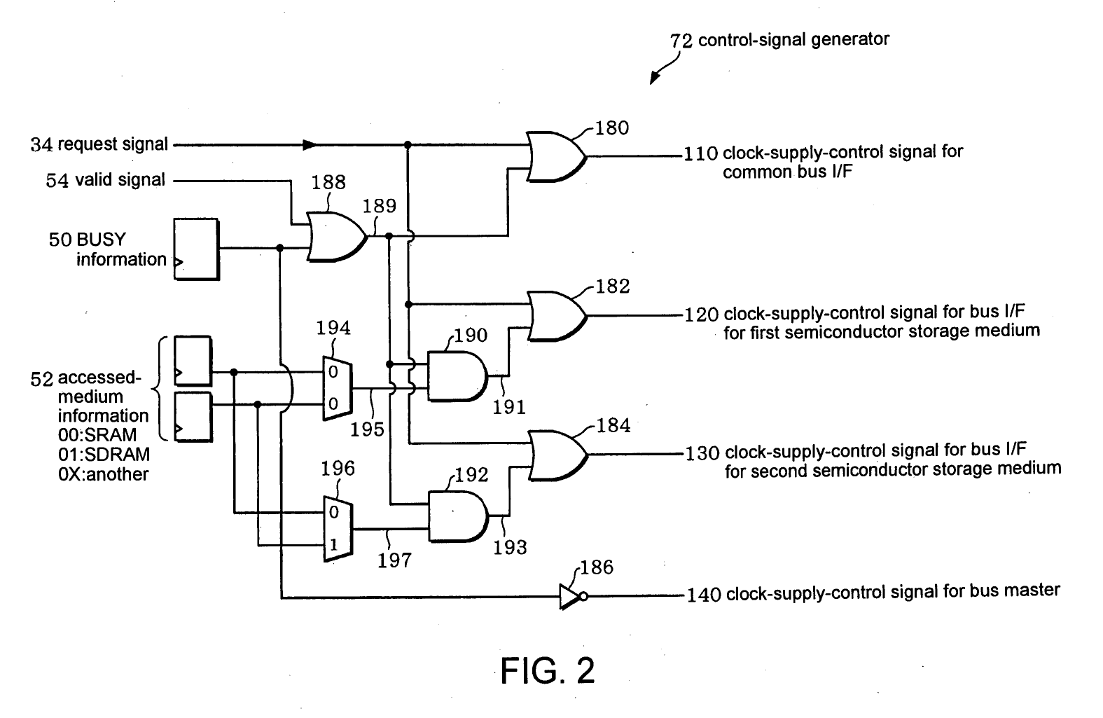

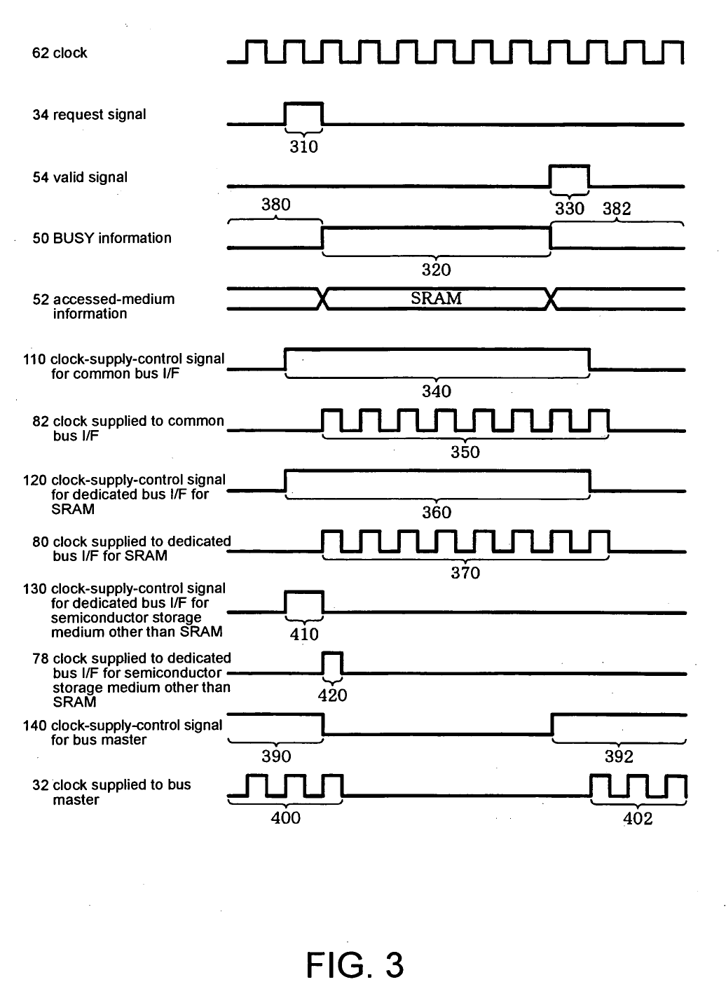

FIG. 2 is a diagram for explaining an example of the structure of the control-signal generator 72 of the present embodiment. FIG. 3 is a timing chart diagram of each signal of FIG. 2.

A numeral 34 shows a request signal for access (read/write) to a semiconductor storage medium that is output from the bus master 90 (for example, the CPU 22, the cache 24, the MMU 26, and the DMAC 30) to the bus interface.

A numeral 50 shows BUSY information, where one-bit information indicating the BUSY state and idle state of the bus interface is used.

A numeral 52 shows accessed-medium information, which is information for identifying the semiconductor storage medium at a state of being accessed. Here, two-bit information is used. The information can be associated with each semiconductor storage medium so that, for example, “00” corresponds to a first semiconductor storage medium (for example, an SRAM), “01” to a second semiconductor storage medium (for example, an SDRAM), and so on.

A numeral 54 shows a valid signal, which is enabled when data accessed by the bus interface is sent in the bus.

A clock-supply-control signal 110 for common bus interface is a signal for instructing the supply or stop of a clock to the common bus interface.

A clock-supply-control signal 120 for dedicated bus interface for first semiconductor storage medium is a signal for instructing the supply or stop of a clock to the dedicated bus interface for first semiconductor storage medium.

A clock-supply-control signal 130 for dedicated bus interface for second semiconductor storage medium is a signal for instructing the supply or stop of a clock to the dedicated bus interface for second semiconductor storage medium.

A clock-supply-control signal 140 for bus master is a signal for instructing the supply or stop of a clock to a CPU, a MMU, a cache, etc. that function as a bus master.

The control-signal generator 72 includes a first OR circuit 180. The first OR circuit 180 outputs the clock-supply-control signal for common bus interface, based on OR condition between the request signal 43 and an output signal 189 from a second OR circuit 188.

The control-signal generator 72 includes the second OR circuit 188. The second OR circuit 188 produces an output signal 190, based on OR condition between the valid signal 54 and the BUSY information (signal).

The control-signal generator 72 includes a third OR circuit 182. The third OR circuit 182 produces the clock-supply-control signal 120 for dedicated bus interface for first semiconductor storage medium, based on OR condition between the request signal 43 and an output signal 191 from a first AND circuit 190.

The control-signal generator 72 includes a fourth OR circuit 184. The fourth OR circuit 184 produces the clock-supply-control signal 130 for dedicated bus interface for second semiconductor storage medium, based on OR condition between the request signal 43 and an output signal 193 from a second AND circuit 192.

The control-signal generator 72 includes the first AND circuit 190. The first AND circuit 190 produces the output signal 191, based on AND condition between the output signal 189 from the second OR circuit 188 and an output signal 185 from a first comparator 194.

The control-signal generator 72 includes the second AND circuit 192. The second AND circuit 192 produces the output signal 193, based on AND condition between the output signal 189 from the second OR circuit 188 and an output signal 187 from a second comparator 196.

The control-signal generator 72 includes an inverter 186. The inverter 186 produces the clock-supply-control signal 140 for bus master, based on NOT condition of the BUSY information (signal).

According to the present embodiment, during the period when the bus master requests (refer to 310 of FIG. 3), the bus interface is at a BUSY state (refer to 320 of FIG. 3), or the bus interface outputs the valid signal (refer to 330 of FIG. 3), the clock-supply-control signal for common bus interface is enabled (H level) (refer to 340 of FIG. 3), enabling a clock to be supplied to the common bus interface (refer to 350 of FIG. 3).

Meanwhile, when none of the conditions where the bus master requests, the bus interface is at a BUSY state, and the bus interface outputs the valid signal is satisfied, the supply of a clock to the common bus interface may be stopped by turning the clock-supply-control signal for common bus interface to be disabled (L level).

Moreover, during the period when the bus master requests (refer to 310 of FIG. 3), the bus interface is at a BUSY state (refer to 320 of FIG. 3), or the bus interface outputs the valid signal (refer to 330 of FIG. 3), the clock-supply-control signal for dedicated bus interface for the semiconductor storage medium to be accessed is turned to “on” (for example, H level) (refer to 360 of FIG. 3), enabling a clock to be supplied to the dedicated bus interface for the semiconductor storage medium to be accessed (refer to 360 of FIG. 3).

In addition, the supply of a clock to the dedicated bus interface for the semiconductor storage medium to be accessed may be stopped by turning the clock-supply-control signal for dedicated bus interface for the semiconductor storage medium not to be accessed, to be disabled (L level).

According to the present embodiment, during the period when the bus interface is not at a BUSY state (refer to 380 and 382 of FIG. 3), the clock-supply-control signal for bus master is disabled (H level) (refer to 390 and 392 of FIG. 3), enabling a clock to be supplied to the bus master (refer to 400 and 402 of FIG. 3).

Meanwhile, during the period when the bus interface is at a BUSY state, the supply of a clock to the bus master may be stopped by turning the clock-supply-control signal for bus master to be disabled (L level).

Here, if the request signal from the bus master is turned to H level, once the clock-supply-control signals for bus interface to all blocks belonging to the bus interface block may be enabled (H level). This makes the merit that the clock-supply-control signal for dedicated bus interface for the semiconductor storage medium not to be accessed can also quickly respond to being enabled (H level) (refer to 410 of FIG. 3) and the request.

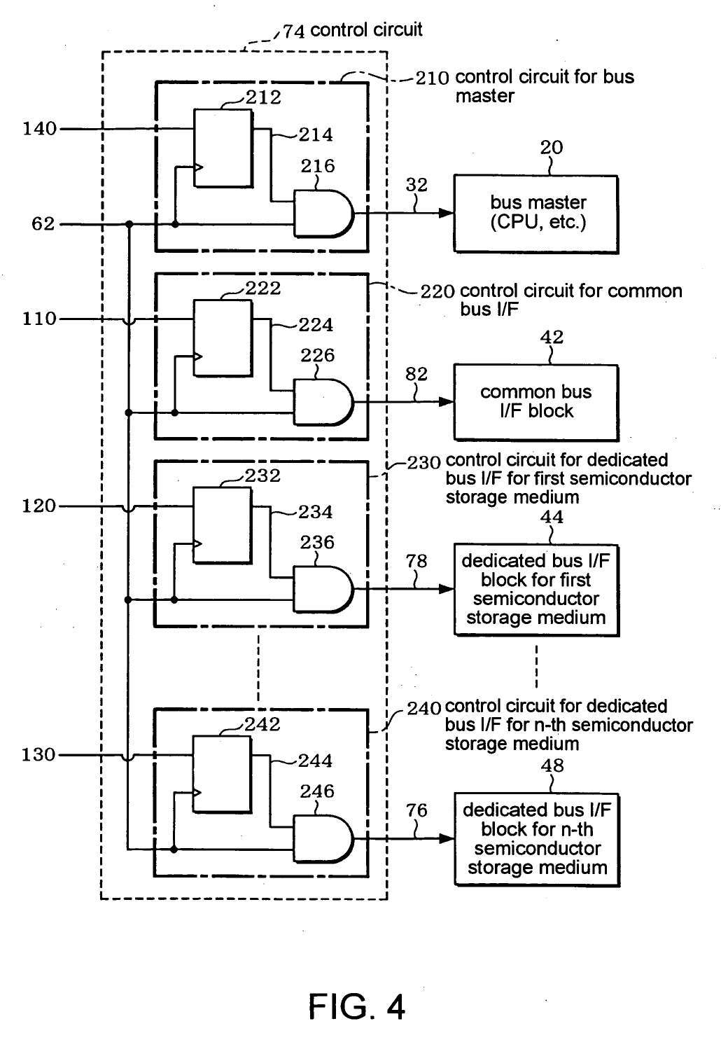

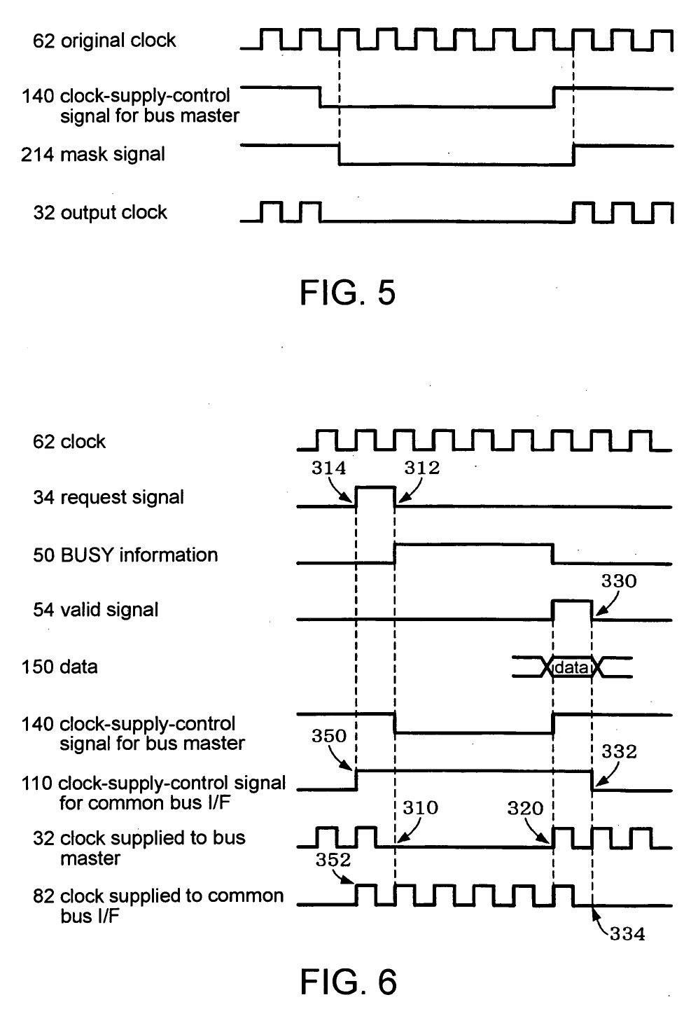

FIG. 4 is a diagram for explaining an example of the structure of the control circuit 74 of the present embodiment. FIG. 5 is a timing chart diagram of each signal of FIG. 4.

The control circuit 74 can include a control circuit 210 for bus master. The control circuit 210 for bus master controls the supply or stop of the clock 32 to the bus master block 20, such as a CPU, based on the clock-supply-control signal 140 for bus master and a clock 62 generated from the clock generator. The control circuit 210 for bus master may include, for example, a latch circuit 212 and an AND circuit 216. The latch circuit 212 may produce a mask signal 214 based on the clock-supply-control signal 140 for bus master and the clock 62 generated from the clock generator. The AND circuit 216 may produce the clock 32 supplied to the bus master block 20 based on AND condition between the mask signal 214 and the clock 62 (refer to FIG. 5).

The control circuit 74 can include a control circuit 220 for common bus interface. The control circuit 220 for common bus interface controls the supply or stop of a clock 82 to the common bus interface block 42, based on the clock-supply-control signal 110 for common bus interface and the clock 62 generated from the clock generator. The control circuit 220 for common bus interface may include, for example, a latch circuit 222 and an AND circuit 226. The latch circuit 222 may produce a mask signal 224 based on the clock-supply-control signal 110 for common bus interface and the clock 62 generated from the clock generator. The AND circuit 226 may produce the clock 82 supplied to the common bus interface block 42 based on AND condition between the mask signal 224 and the clock 62.

The control circuit 74 can include a control circuit 230 for dedicated bus interface for first semiconductor storage medium. The control circuit 230 for dedicated bus interface for first semiconductor storage medium controls the supply or stop of a clock 78 to the dedicated bus interface block 44 for first semiconductor storage medium, based on the clock-supply-control signal 120 for dedicated bus interface for first semiconductor storage medium and the clock 62 generated from the clock generator. The control circuit 230 for dedicated bus interface for first semiconductor storage medium may include, for example, a latch circuit 232 and an AND circuit 236. The latch circuit 232 may produce a mask signal 234 based on the clock-supply-control signal 120 for dedicated bus interface for first semiconductor storage medium and the clock 62 generated from the clock generator. The AND circuit 236 may produce the clock 78 supplied to the dedicated bus interface block 44 for first semiconductor storage medium based on AND condition between the mask signal 234 and the clock 62.

The control circuit 74 may include a control circuit 240 for dedicated bus interface for n-th semiconductor storage medium. The control circuit 240 for dedicated bus interface for n-th semiconductor storage medium controls the supply or stop of a clock 76 to a dedicated bus interface block 48 for n-th semiconductor storage medium, based on the clock-supply-control signal 130 for dedicated bus interface for n-th semiconductor storage medium and the clock 62 generated from the clock generator. The control circuit 240 for dedicated bus interface for n-th semiconductor storage medium may include, for example, a latch circuit 242 and an AND circuit 246. The latch circuit 242 may produce a mask signal 244 based on the clock-supply-control signal 130 for dedicated bus interface for n-th semiconductor storage medium and the clock 62 generated from the clock generator. The AND circuit 246 may produce the clock 76 supplied to the dedicated bus interface block 48 for n-th semiconductor storage medium based on AND condition between the mask signal 244 and the clock 62.

FIG. 6 is a diagram for explaining about the periods when a clock is supplied to the given bus master block and when a clock is supplied to the bus interface block. As shown in the diagram, the clock-supply-control signal 140 for bus master is turned to L level (disabled) after the request signal 34 changes from H level to L level, and thereby the supply of a clock to the bus master block can be stopped after the completion of the request output from the bus master block. Here, after the completion of the request from the bus master block can mean the time when the request signal output from the bus master block turns down the request (for example, the time when the request signal 34 changes from H to L), and the like.

In order to stop a clock supplied to the bus master block after the completion of the request from the bus master block, for example, the supply of a clock to the bus master block may be stopped after the completion of the request from the bus master block is detected (for example, after the change of the request signal 34 from H level to L level is detected).

The clock 32 supplied to the bus master block may be stopped after the bus interface block changes from a non-BUSY state to a BUSY-state (after the BUSY signal changes from L level to H level), or after at least the time of one clock passes after the change (during this time, the request from the bus master block is completed). This enables a clock to be supplied to the bus master (refer to 310) until the bus master turns down the request signal (refer to 312).

A clock can be supplied to the bus master where a waiting state is completed (refer to 320), by turning the clock-supply-control signal 140 for bus master to H level at the period when the BUSY signal is at a non-BUSY state (idle state) and at the timing when the valid signal 54 is enabled (changes from L level to H level).

As shown in the same drawing, the valid signal 54 output from the bus interface block is completed (the valid signal changes from H level to L level) (refer to 330), and thereafter the clock-supply-control signal 140 for bus interface is turned to L level (disabled) (refer to 332), enabling the supply of the clock 82 to the bus interface block to be stopped (refer to 334).

Here, the bus interface block may be the common bus interface block, or may be the dedicated bus interface block. The clock-supply-control signal for bus interface may be the clock-supply-control signal for common bus interface, or may be the clock-supply-control signal for dedicated bus interface.

The case where the supply of a clock to the bus interface block is stopped after the bus interface block outputs the valid signal 54 may be the case where, for example, the supply of a clock to the bus interface block is stopped after the output of the valid signal 54 from the bus interface block is detected. Otherwise, that may be the case where the supply of a clock to the bus interface block is stopped after the bus interface block changes from a BUSY state to a non-BUSY state (after the BUSY signal changes from H level to L level), or after at least the time of one clock passes after the change (during the period, the bus interface block outputs the valid signal). This enables a clock to be supplied to the bus interface block (refer to 334) until the bus interface turns down the valid signal 54 (refer to 330).

The clock-supply-control signal 140 for bus interface is turned to H level (refer to 350) at the timing when the request signal 34 is enabled (changes from L level to H level), and thereby a clock can be supplied to the bus interface (refer to 352), enabling quick response to the request from the bus master and successive operation.

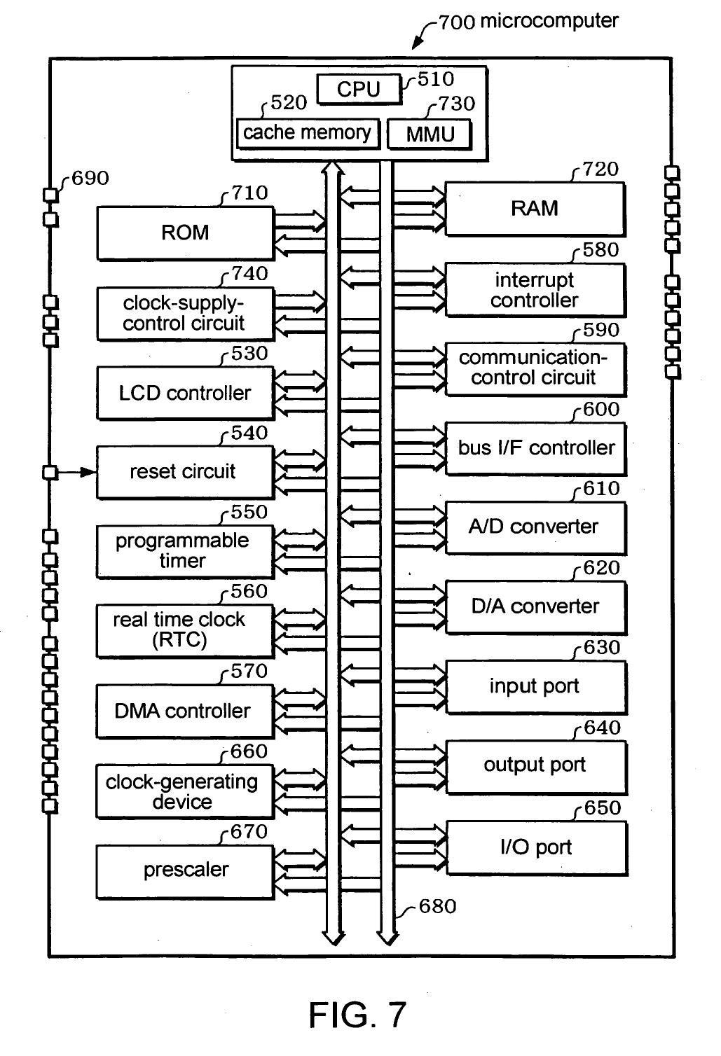

FIG. 7 is an example of an exemplary hardware block diagram of a microcomputer including the semiconductor device or the semiconductor circuit of the present embodiment. A microcomputer 700 can include a CPU 510, a cache memory 520, a memory management unit (MMU) 730, an LCD controller 530, a reset circuit 540, a programmable timer 550, a real time clock (RTC) 560, a DMA controller 570, an interrupt controller 580, a communication control circuit 590, a bus controller 600, an A/D converter 610, an D/A converter 620, an input port 630, an output port 640, an I/O port 650, a clock-generating device 660, a prescaler 670, and a clock-supply-control circuit 740. The microcomputer 700 also includes various buses 680, various pins 690 and the like that interconnect the above elements.

The clock-supply-control circuit 740 has the structure, for example, described with FIGS. 1 through 6.

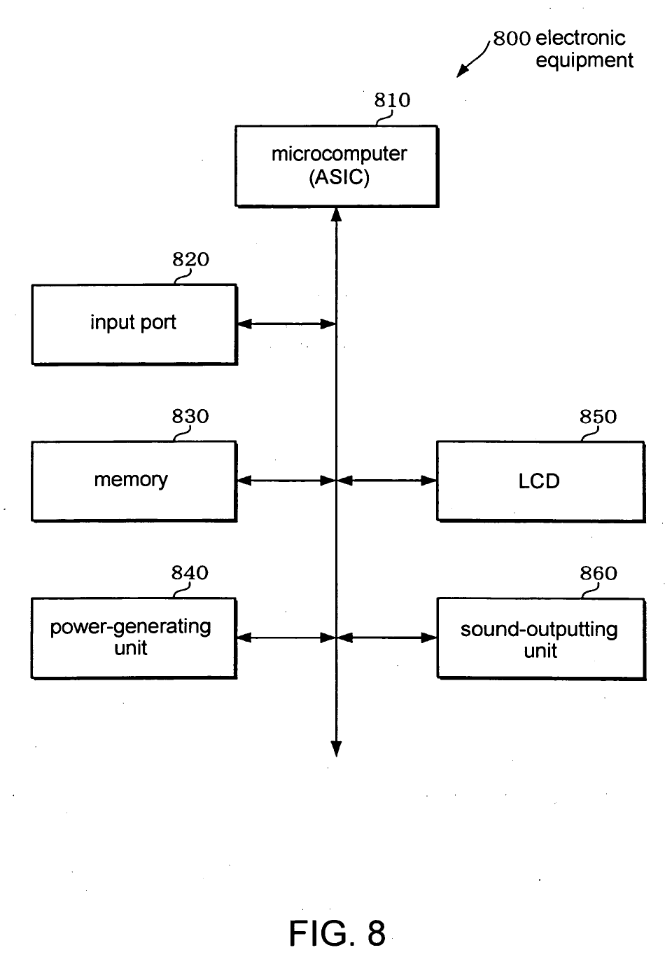

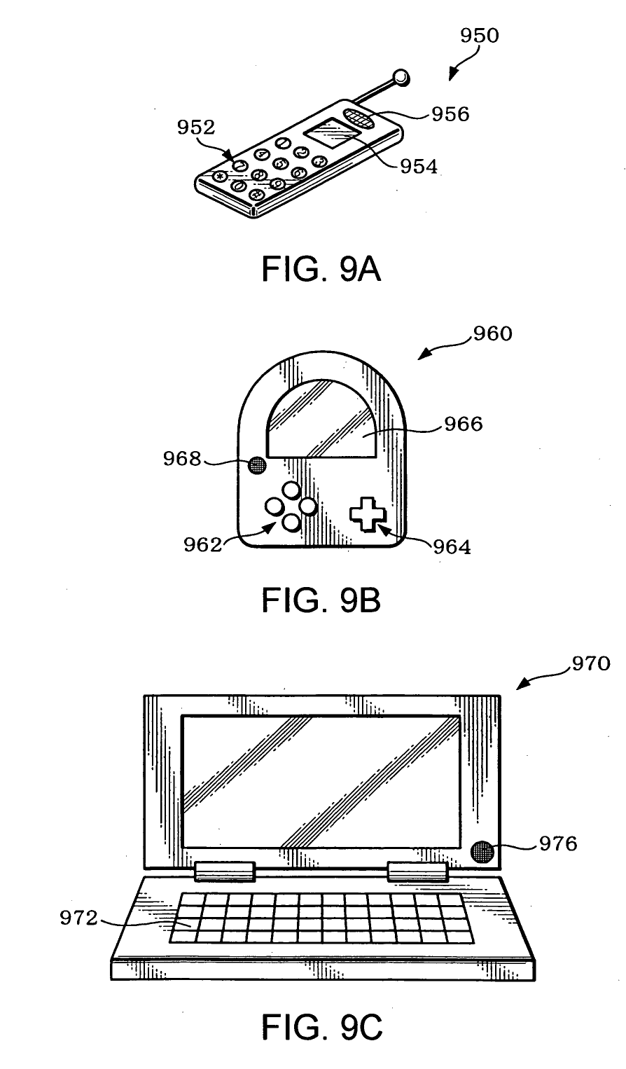

FIG. 8 is an example of a block diagram of electronic equipment of the present embodiment. Electronic equipment 800 includes a microcomputer (or ASIC) 810, an input part 820, a memory 830, a power-generating unit 840, an LCD 850, and a sound-outputting unit 860.

The input part 820 inputs various data. The microcomputer 810 performs various processing based on the data input by the input part 820. The memory 830 functions as a work area for the microcomputer 810 and the like. The power-generating unit 840 generates various power used in the electronic equipment 800. The LCD 850 outputs various images (character, icon, graphic and the like) shown by electronic equipment. The sound-outputting unit 860 outputs various sounds (audio, game sound, etc.) output from the electronic equipment 800. The function thereof is realized by way of hardware, such as a speaker.

The microcomputer (or ASIC) 810 has the structure, for example, described with FIG. 7.

FIG. 9(A) shows an example of an external view of a cellular phone 950, which is one of electronic equipment. The cellular phone 950 includes a dial button 952 functioning as an input part, an LCD 954 displaying a phone number, a name, an icon, etc., and a speaker 956 that functions as a sound-outputting unit and outputs sounds.

FIG. 9(B) shows an example of an external view of a portable game device 960, which is one of electronic equipment. The portable game device 960 includes operation buttons 962 functioning as input parts, a cross key 964, an LCD 966 displaying game images, and a speaker 968 that functions as a sound-outputting unit and outputs game sounds.

FIG. 9(C) shows an example of an external view of a personal computer 970, which is one of electronic equipment. The personal computer 970 includes a key board 972 functioning as an input part, an LCD 974 displaying characters, figures, graphics, etc., and a sound-outputting unit 976.

In addition, other than equipment shown in FIGS. 9(A) through (C), various electronic equipment using an LCD, such as a portable information terminal, a pager, a electronic desktop calculator, a device having a touch panel, a projector, a word processor, a view finder type or monitoring type video tape recorder, a car navigation system, and the like, may be considered as electronic equipment utilizing the present embodiment.

Here, it should be understood that the present invention is not limited to the present invention, but can be applied to various kinds of modifications within the scope and spirit of the present invention.

In the present embodiment, the case where the clock-supply-control circuit controls both of the presence of the supply of a clock to the bus master and that to the bus interface, has been described as an example. It should also be understood that the clock-supply-control circuit, however, may control either of them.

What is claimed is:

1. A semiconductor device that accesses at least one semiconductor storage medium, comprising:
a bus master;
a bus interface that controls access to the at least one semiconductor storage medium based on a request for access to the at least one semiconductor storage medium from the bus master; and
a clock-supply-control circuit that controls the presence of the supply of a clock to the bus master based on access state information that indicates a state of access to the at least one semiconductor storage medium, the clock-supply-control circuit including a circuit that implements at least one of control for stopping the supply of the clock to the bus master if the circuit determines that the bus interface is at a BUSY state, and control for supplying the clock to the bus master if the circuit determines that the bus interface is at a non-BUSY state, based on the access state information.

2. The semiconductor device according to claim 1, the clock-supply-control circuit implementing a processing to stop the supply of the clock to the bus master after completion of request output from the bus master.

3. A semiconductor circuit that controls a presence of a supply of a clock to a bus master, comprising:
a control-signal generator that generates a clock-supply-control signal for the bus master that instructs the presence of the supply of the clock to the bus master, based on access state information that indicates a state of access to at least one semiconductor storage medium; and
a control circuit that controls the presence of the supply of the clock generated from a clock generator to the bus master, based on the clock-supply-control signal for bus master,
the control-signal generator disabling the clock-supply-control signal for the bus master if access state information indicates that access is in execution; and
the control circuit including a circuit that controls so as to stop the supply of the clock generated from the clock generator to the bus master if the clock-supply-control signal for the bus master is disabled.

4. The semiconductor circuit according to claim 3, the control-signal generator disabling the clock-supply-control signal for the bus master after the completion of request output from the bus master.

5. Electronic equipment, comprising:
a semiconductor device that includes the semiconductor device according to claim 1;
a receiving device that receives input information; and
an output device that outputs a result processed by an information-processing device based on the input information.

6. Electronic equipment, comprising:
a semiconductor device that includes the semiconductor device according to claim 3;
a receiving device that receives input information; and
an output device that outputs a result processed by an information-processing device based on the input information.

7. A method of controlling clock-supply that controls a presence of a supply of a clock to a bus master of a semiconductor device, comprising:
generating a clock-supply-control signal for the bus master that instructs a presence of the supply of the clock to the bus master, based on access state information that indicates a state of access to at least one semiconductor storage medium; and
controlling the presence of the supply of the clock generated from a clock generator to the bus master, based on the clock-supply-control signal for the bus master,
the clock-supply-control signal for the bus master being disabled if access state information indicates that access is in execution; and
control to stop the supply of the clock generated from the clock generator to the bus master being implemented if the clock-supply-control signal for the bus master is disabled.

8. The method of controlling clock-supply according to claim 6, the clock-supply-control signal for bus master being disabled after a completion of request output from the bus master.
